(19) United States
(12) Patent Application Publication
(10) Pub. No.: US 2025/0323165 A1
(43) Pub. Date: Oct. 16, 2025

(54) SEMICONDUCTOR DEVICE AND MANUFACTURING METHOD FOR SEMICONDUCTOR DEVICE

(71) Applicant: Fujian Jinhua Integrated Circuit Co., Ltd., Fujian (CN)

(72) Inventors: Zunkun TAN, Fujian (CN); Jingjing YOU, Fujian (CN); Kunlin WU, Fujian (CN); Weiting LIU, Fujian (CN)

(73) Assignee: Fujian Jinhua Integrated Circuit Co., Ltd., Fujian (CN)

(21) Appl. No.: 18/889,270

(22) Filed: Sep. 18, 2024

(30) Foreign Application Priority Data
Apr. 12, 2024 (CN) 202410444709.4

(51) Int. Cl. H01L 23/535; H01L 21/768

(52) U.S. Cl. CPC H01L 23/535; H01L 21/76831; H01L 21/76843; H01L 21/76895

(57) ABSTRACT

The present application provides a semiconductor device and a manufacturing method for the semiconductor device, which relates to the field of semiconductor technology, for solving a technical problem of poor device performance. The semiconductor device includes a stacked structure, a connection structure, and a first insulation layer, where the connection structure runs through the stacked structure, and includes a metal core located inside the stacked structure, a metal oxide layer located on a sidewall of the metal core, and a barrier layer located between the metal oxide layer and the metal core. A top surface of the metal oxide layer and a top surface of the barrier layer are not equal in height and the metal oxide layer is in direct contact with the stacked structure. The first insulation layer is in direct contact with the sidewall of the metal core.

### CROSS-REFERENCE TO RELATED APPLICATIONS

This application claims priority to Chinese Patent Application No. 202410444709.4, filed on Apr. 12, 2024, which is hereby incorporated by reference in its entirety.

### TECHNICAL FIELD

The present application relates to the field of semiconductor technology and, in particular, to a semiconductor device and a manufacturing method for the semiconductor device.

### BACKGROUND

With the continuous development of technology, application of semiconductor devices is becoming increasingly widespread. For example, a semiconductor device may include a transistor, which typically includes a source region, a drain region, a channel region located between the source region and the drain region, a gate dielectric layer located at least in the channel region, and a gate located on the gate dielectric layer. The transistor utilizes an electric field created by the gate to control a quantity of induced charges within the channel region, thereby changing a state of the channel region and achieving an effect of controlling a current in the drain region.

As feature sizes of the semiconductor devices shrink, production cost of the semiconductor devices is getting higher and a yield rate is getting lower. The development of planar semiconductor devices has reached a bottleneck, and the semiconductor devices with three-dimensional structures, such as a three-dimensional NAND flash memory, have become a mainstream development trend. However, the existing semiconductor devices still have many defects, which need to be further improved to effectively enhance efficiency and a reliability of the related semiconductor devices.

### SUMMARY

In view of the above issues, embodiments of the present application provide a semiconductor device and a manufacturing method for the semiconductor device to reduce leakage of electricity of the semiconductor device and improve performance of the semiconductor device.

According to some embodiments, a first aspect of the present application provides a semiconductor device, including:
a stacked structure, where the stacked structure includes alternating disposed metal layers and spacer layers;
a connection structure, where the connection structure runs through the stacked structure, and the connection structure includes a metal core located inside the stacked structure, a metal oxide layer located on a sidewall of the metal core, and a barrier layer located between the metal oxide layer and the metal core; and
a first insulation layer, where the first insulation layer is in direct contact with the sidewall of the metal core;
where a top surface of the metal oxide layer and a top surface of the barrier layer are not equal in height and the metal oxide layer is in direct contact with the stacked structure.

According to some embodiments, a second aspect of the present application provides a manufacturing method for a semiconductor device, including:
forming a stacked structure, where the stacked structure includes alternating disposed metal layers and spacer layers;
forming a connection structure, where the connection structure runs through the stacked structure, and the connection structure includes a metal core located inside the stacked structure, a metal oxide layer located on a sidewall of the metal core, and a barrier layer located between the metal oxide layer and the metal core; where a top surface of the metal oxide layer and a top surface of the barrier layer are not equal in height and the metal oxide layer is in direct contact with the stacked structure; and
forming a first insulation layer, where the first insulation layer is in direct contact with the sidewall of the metal core.

The embodiments of the present application provide the semiconductor device and the manufacturing method for the semiconductor device, in which the connection structure runs through the stacked structure, and the connection structure includes the metal core located inside the stacked structure, the metal oxide layer located on the sidewall of the metal core, and the barrier layer located between the metal oxide layer and the metal core. The barrier layer can prevent diffusion of metal ions inside the metal core to the metal oxide layer, thereby ensuring a performance of the metal oxide layer. The top surface of the metal oxide layer and the top surface of the barrier layer are not equal in height and the metal oxide layer is in direct contact with the stacked structure. The first insulation layer is in direct contact with the sidewall of the metal core to isolate the metal cores from each other, which can reduce leakage of electricity of the metal core and improve performance of the semiconductor device.

### BRIEF DESCRIPTION OF DRAWINGS

FIG. 1 is a schematic diagram of a semiconductor device provided by an embodiment of the present application.

FIG. 2 is another schematic diagram of a semiconductor device provided by an embodiment of the present application.

FIG. 3 is a first partial enlarged view of a metal oxide layer and a barrier layer provided by an embodiment of the present application.

FIG. 4 is a second partial enlarged view of a metal oxide layer and a barrier layer provided by an embodiment of the present application.

FIG. 5 is a third partial enlarged view of a metal oxide layer and a barrier layer provided by an embodiment of the present application.

FIG. 6 is a fourth partial enlarged view of a metal oxide layer and a barrier layer provided by an embodiment of the present application.

FIG. 7 is a fifth partial enlarged view of a metal oxide layer and a barrier layer provided by an embodiment of the present application.

FIG. 8 is a sixth partial enlarged view of a metal oxide layer and a barrier layer provided by an embodiment of the present application.

FIG. 9 is a flowchart of a manufacturing method for a semiconductor device provided by an embodiment of the present application.

FIG. 10 is a schematic diagram of a stacked structure after being formed of an embodiment of the present application.

FIG. 11 is a schematic diagram of a hole structure after being formed of an embodiment of the present application.

FIG. 12 is a schematic diagram of sacrificial material after being formed of an embodiment of the present application.

FIG. 13 is a schematic diagram of a metal oxide layer after being formed of an embodiment of the present application.

FIG. 14 is a schematic diagram of metal material after being formed of an embodiment of the present application.

FIG. 15 is a schematic diagram of protective material after being formed of an embodiment of the present application.

FIG. 16 is a schematic diagram of a concavity after being formed of an embodiment of the present application.

FIG. 17 is a schematic diagram of a first insulation layer after being formed of an embodiment of the present application.

FIG. 18 is a partially enlarged view at A in FIG. 17.

### DESCRIPTION OF EMBODIMENTS

To understand the above objectives, features, and advantages of the embodiments of the present application more clearly, technical solutions in the embodiments of the present application will be clearly and completely described below in combination with the accompanying drawings of the embodiments of the present application. It is clear that the embodiments described are a part of the embodiments of the present application, and not all of them. Based on the embodiments of the present application, all other embodiments obtained by persons of ordinary skill in the art without creative effort fall within the scope of protection of the present application.

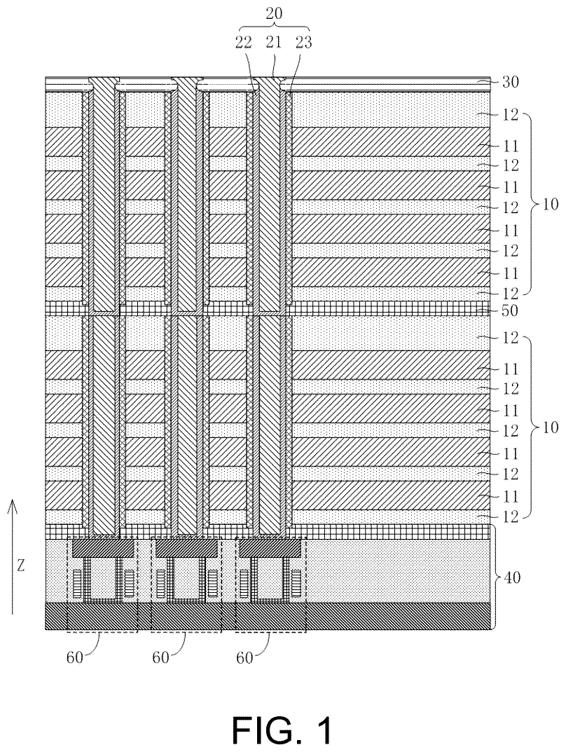

Referring to FIG. 1, FIG. 1 is a schematic diagram of a semiconductor device provided by an embodiment of the present application, the semiconductor device includes a stacked structure 10, a connection structure 20, and a first insulation layer 30. The stacked structure 10 includes alternating disposed metal layers 11 and spacer layers 12, and a stacking direction thereof can be vertical, as shown in a direction Z in FIG. 1.

Where, the metal layers 11 and the spacer layers 12 all can be disposed with at least two layers. Exemplarily, as shown in FIG. 1, the metal layer 11 is disposed with four layers, and the spacer layer 12 is disposed with five layers. Along a vertical direction, the four metal layers 11 and the five spacer layers 12 are disposed alternately. One metal layer 11 is disposed between the two adjacent spacer layers 12, and one spacer layer 12 is disposed between the two adjacent metal layers 11.

The metal layer 11 is made of metal material, for example, the material of metal layer 11 includes tungsten or tungsten alloy. The spacer layer 12 is made of insulation material to isolate the adjacent metal layers 11. For example, the material of the spacer layer 12 includes silicon oxide, silicon oxynitride, silicon nitride, carbon nitride, etc., and the silicon oxide can be generated by tetraethoxysilane (TEOS).

In some possible embodiments, the stacked structure 10 is located on a substrate (not shown), which may include a silicon substrate, a germanium substrate, a silicon germanium substrate, a silicon carbide substrate, an epitaxial silicon substrate, a silicon on insulator (SOI) substrate, or a germanium on insulator (GOI) substrate, or substrates made of other suitable materials, but not limited thereto. Persons of ordinary skill in the art should be able to easily understand that various active and/or passive components can be further formed on or within the substrate according to actual requirements of the device.

A second insulation layer 40 can also be disposed between the stacked structure 10 and the substrate, and a device structure can be formed inside the second insulation layer 40. For example, at least one transistor 60 is formed inside the second insulation layer 40. In some possible embodiments, the second insulation layer 40 includes at least two sub-layers, which are made of different materials. For example, the material of the sub-layer near the substrate may include silicon oxide, silicon nitride, etc., while the material of the sub-layer away from the substrate may include aluminum oxide, hafnium oxide, zirconia, tantalum oxide, etc. The transistor 60 includes a source, a drain, a gate, and a channel, where the source and the drain are disposed relatively. For example, the drain is exposed on a top surface of the sub-layer near the substrate in the second insulation layer 40, and the source is located inside the sub-layer and in contact with the substrate. The channel can be cylindrical, a bottom thereof is in contact with the source and an opening thereof is in contact with the drain. For example, some drains extend into the opening, and insulation material is filled between the source and the drain. The gate surrounds the channel and is disposed at intervals from the channel.

Continuing to refer to FIG. 1, the connection structure 20 runs through the stacked structure 10, and the connection structure 20 includes a metal core 21, a metal oxide layer 23, and a barrier layer 22. The metal core 21 is located inside the stacked structure 10 and runs through the stacked structure 10. As shown in FIG. 1, a top surface of the metal core 21 is exposed to a top surface of the stacked structure 10, and a top end of the metal core 21 can extend outward from the stacked structure 10. A bottom surface of the metal core 21 is exposed to a bottom surface of the stacked structure 10, and a bottom end of the metal core 21 can extend outward from the stacked structure 10. The metal core 21 can extend along the stacking direction of the stacked structure 10 to facilitate preparation of the metal core 21. The metal core 21 is made of metal material, such as tungsten and tungsten alloy.

The metal oxide layer 23 is located on a sidewall of the metal core 21, and the barrier layer 22 is located between the metal oxide layer 23 and the metal core 21. The barrier layer 22 separates the metal oxide layer 23 from the metal core 21, which prevents diffusion of metal ions inside the metal core 21 into the metal oxide layer 23, thereby ensuring insulation performance of the metal oxide layer 23. The metal oxide layer 23 isolates the metal core 21 and/or the barrier layer 22 from the stacked structure 10, thereby ensuring electrical performance of the semiconductor device.

Where, the barrier layer 22 is in direct contact with the sidewall of the metal core 21, the metal oxide layer 23 is in direct contact with a sidewall of the barrier layer 22 away from the metal core 21 (i.e., an outer sidewall of the barrier layer 22), and the materials of the barrier layer 22 can include titanium nitride, tantalum nitride, etc. The metal oxide layer 23 is in direct contact with the stacked structure 10, for example, a sidewall of the metal oxide layer 23 away from the metal core 21 (i.e. an outer sidewall of the metal oxide layer 23) is in direct contact with the stacked structure 10 to insulate the stacked structure 10 by using the metal oxide layer 23.

In some possible embodiments, two ends of the metal oxide layer 23 are flush with the metal layers 11 located on both sides of the stacked structure 10, which ensures that the metal oxide layer 23 can separate each metal layer 11 from the metal core 21 and/or the barrier layer 22. The materials of metal oxide layer 23 can include hafnium silicon oxide, hafnium oxide, zirconia, tantalum oxide, titanium oxide, etc. In this way, the metal oxide layer 23 has a high dielectric constant, which can improve insulation performance thereof.

Continuing to refer to FIG. 1, a top surface of the metal oxide layer 23 and a top surface of the barrier layer 22 are not equal in height, that is, the top surface of the metal oxide layer 23 and the top surface of the barrier layer 22 are not flush. Specifically, in a process of forming the metal oxide layer 23 and barrier layer 22, etching process parameters are adjusted to enable etching gas or etching solution to etch the metal oxide layer 23 and barrier layer 22 with different etching rates, thereby forming the metal oxide layer 23 and the barrier layer 22 with a height difference between their top surfaces.

As an embodiment, the top surface of the metal oxide layer 23 is higher than the top surface of the barrier layer 22, that is, the top surface of the barrier layer 22 is lower than the top surface of the metal oxide layer 23.

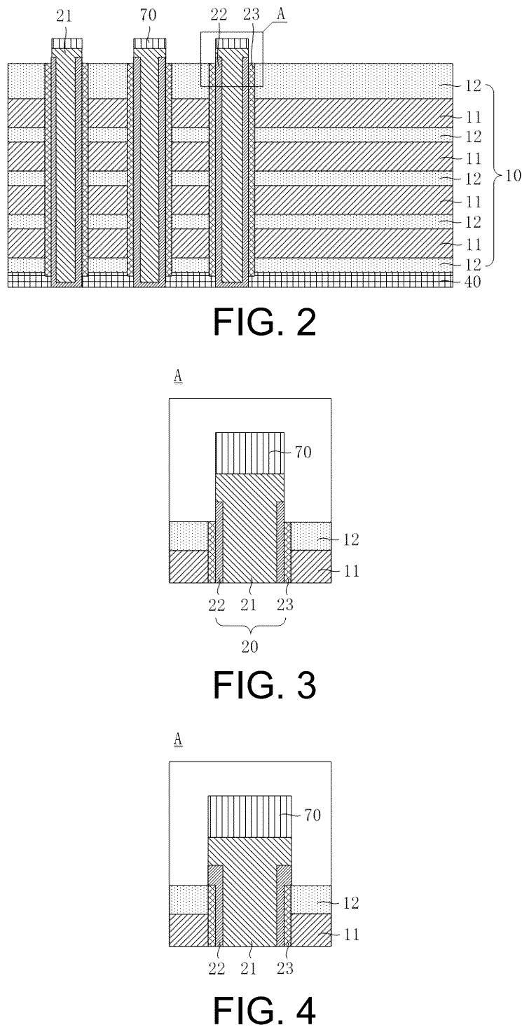

As another embodiment, referring to FIG. 2 to FIG. 4. FIG. 2 is another schematic diagram of a semiconductor device provided by an embodiment of the present application, FIG. 3 is a first partial enlarged view of a metal oxide layer and a barrier layer provided by an embodiment of the present application, and FIG. 4 is a second partial enlarged view of a metal oxide layer and a barrier layer provided by an embodiment of the present application. As shown in FIG. 2 to FIG. 4, the top surface of the barrier layer 22 is higher than the top surface of the metal oxide layer 23, that is, the top surface of the metal oxide layer 23 is lower than the top surface of the barrier layer 22. In this way, a barrier effect of the barrier layer 22 can be improved, and a contact between the metal oxide layer 23 and the metal core 21 can be effectively avoided.

In some possible implementations, as shown in FIG. 4, the barrier layer 22 is in direct contact with the top surface of the metal oxide layer 23. An outer sidewall at a top end of the barrier layer 22 protrudes to a direction away from the metal core 21, thereby extending to the top surface of the metal oxide layer 23, which achieves a contact with the metal oxide layer 23. In this way, width sizes of the barrier layer 22 and the metal core 21 can be increased to reduce resistance of the barrier layer 22 and the metal core 21. In an embodiment where a topmost side of the stacked structure 10 is the spacer layer 12, the outer sidewall can also extend to a position above the stacked structure 10.

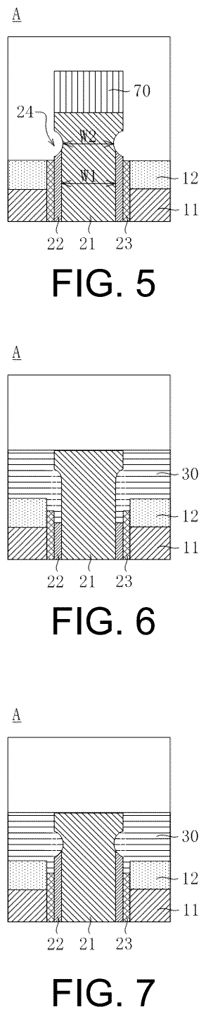

Referring to FIG. 5, FIG. 5 is a third partial enlarged view of a metal oxide layer and a barrier layer provided by an embodiment of the present application. As an embodiment, the top surface of the barrier layer 22 is higher than the top surface of the stacked structure 10, that is, the top end of the barrier layer 22 protrudes from the top end of the stacked structure 10. Where, the top surface of the metal oxide layer 23 and the top surface of the stacked structure 10 can be equal or unequal in height.

Referring to FIG. 6 and FIG. 7, FIG. 6 is a fourth partial enlarged view of a metal oxide layer and a barrier layer provided by an embodiment of the present application, and FIG. 7 is a fifth partial enlarged view of a metal oxide layer and a barrier layer provided by an embodiment of the present application. As an embodiment, the top surface of the metal oxide layer 23 is lower than the top surface of the stacked structure 10, that is, the top end of the metal oxide layer 23 is concaved to the top end of the stacked structure 10, which facilitates preparation of the metal oxide layer 23. Where, the top surface of the barrier layer 22 and the top surface of the stacked structure 10 can be equal or unequal in height. As an embodiment, as shown in FIG. 6, the top surface of the barrier layer 22 is lower than the top surface of the stacked structure 10. As another embodiment, as shown in FIG. 7, the top surface of the barrier layer 22 is higher than the top surface of the stacked structure 10.

Continuing to refer to FIG. 1 and FIG. 2, the first insulation layer 30 is in direct contact with the sidewall of the metal core 21. Specifically, the first insulation layer 30 is in direct contact with a sidewall of a part of the metal core 21 that extends outward from the stacked structure 10 to isolate that part of the metal core 21. A top surface of the first insulation layer 30 can be flush with the top surface of the metal core 21, so that the top surface of the metal core 21 is exposed for the external connection.

In some possible embodiments, the first insulation layer 30 is in direct contact with the top surface of the barrier layer 22, that is, the top surface of the first insulation layer 30 is higher than the top surface of the barrier layer 22, so that the first insulation layer 30 covers the barrier layer 22, thereby avoiding an exposure of the barrier layer 22. As shown in FIG. 7, the top surface of the barrier layer 22 can be higher than the top surface of the metal oxide layer 23, so that the first insulation layer 30 is also in direct contact with the outer sidewall of the barrier layer 22. Or, as shown in FIG. 6, the top surface of the barrier layer 22 can also be lower or flush with the top surface of the metal oxide layer 23, and the first insulation layer 30 is only in direct contact with the top surface of the barrier layer 22.

In some possible embodiments, the first insulation layer 30 is also in direct contact with the top surface of the metal oxide layer 23 at least, that is, the top surface of the first insulation layer 30 is higher than the top surface of the metal oxide layer 23, so that the first insulation layer 30 covers the metal oxide layer 23. Where the top surface of the metal oxide layer 23 can be higher than the top surface of the stacked structure 10, so that the first insulation layer 30 is in direct contact with the top surface and an outer sidewall of the metal oxide layer 23. Or, the top surface of the metal oxide layer 23 can be lower or flush with the top surface of the stacked structure 10, and a contact area between the first insulation layer 30 and the metal oxide layer 23 is related to a height of the top surface of the barrier layer 22. When the top surface of the barrier layer 22 is lower than the top surface of the metal oxide layer 23, the first insulation layer 30 is also in direct contact with an inner sidewall of the metal oxide layer 23. The inner sidewall of the metal oxide layer 23 refers to a sidewall of the metal oxide layer 23 near the metal core 21.

Continuing to refer to FIG. 1 and FIG. 5, in order to increase a spacing between the metal cores 21, the metal core 21 is provided with an inward extended concavity 24, and the concavity 24 is filled by the first insulation layer 30. Where the inward extended refers to extending to a center of the metal core 21. As shown in FIG. 1 and FIG. 5, the metal core 21 includes a first part located inside the stacked structure 10 and a second part extending outside the stacked structure 10, where the first part and second part are integrated. The second part is disposed with the above concavity 24, the first part is provided with a first width W1, the second part is provided with a smallest second width W2, and the second width W2 is smaller than the first width W1, thereby increasing a spacing between the second parts. The first insulation layer 30 is filled in the concavity 24 to reduce leakage of electricity of the second part, thereby reducing leakage of electricity of the metal core 21, and improving performance of the semiconductor device.

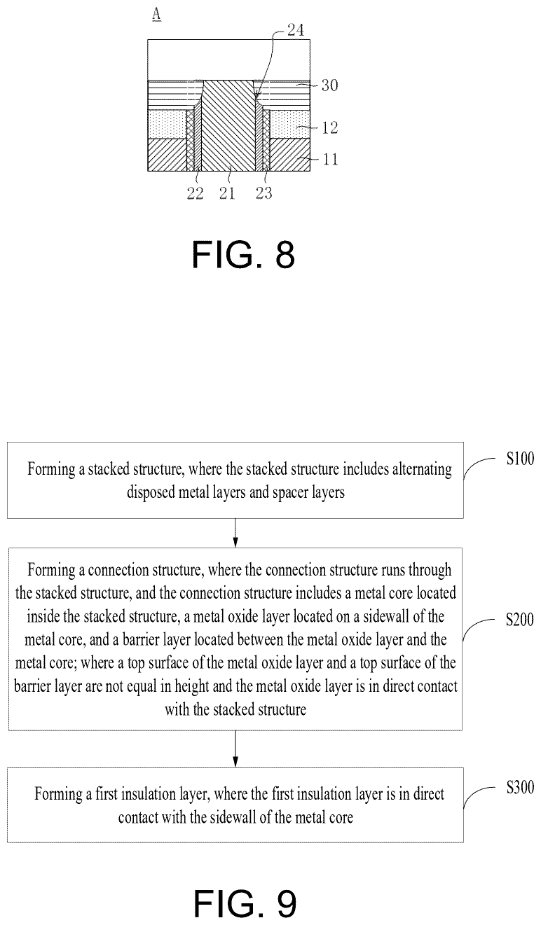

Referring to FIG. 8, FIG. 8 is a sixth partial enlarged view of a metal oxide layer and a barrier layer provided by an embodiment of the present application. A depth of the concavity 24 is gradually increased along a direction closing to the top surface of the metal core 21. In this way, a part of the metal core 21 that extends outward from the stacked structure 10 gradually shrinks upwards, thereby causing a width of the part of the metal core 21 gradually decreases upwards, thereby ensuring the spacing between the metal cores 21. Where a cross-sectional shape of the concavity 24 is not limited, for example, the cross-sectional shape of the concavity 24 can be trapezoidal, or arched or curved.

Continuing to refer to FIG. 1, multiple stacked structures 10 can be disposed and stacked in sequence. A third insulation layer 50 is disposed between adjacent stacked structures 10, and the material of the third insulation layer 50 is different from that of the spacer layer 12 in the stacked structure 10. For example, the material of the third insulation layer 50 includes aluminum oxide. The metal core 21 runs through each stacked structure 10 and the third insulation layer 50 located between adjacent stacked structures 10 to be in electrical connect with the substrate. The metal core 21 can protrude from a topmost stacked structure 10 and is in direct contact with the first insulation layer 30 located on the stacked structure 10.

In summary, the semiconductor device in the embodiments of the present application includes the stacked structure 10, the connection structure 20, and the first insulation layer 30. The stacked structure 10 includes the alternating disposed metal layers 11 and the isolation layers 12, the connection structure 20 runs through the stacked structure 10, and the connection structure 20 includes the metal core 21 located inside the stacked structure 10, the metal oxide layer 23 located on the sidewall of the metal core 21, and the barrier layer 22 located between the metal oxide layer 23 and the metal core 21. The barrier layer 22 can prevent diffusion of metal ions inside the metal core 21 to the metal oxide layer 23, thereby ensuring performance of the metal oxide layer 23. The top surface of the metal oxide layer 23 and the top surface of the barrier layer 22 are not equal in height, and the metal oxide layer 23 is in direct contact with the stacked structure 10. The first insulation layer 30 is in direct contact with the sidewall of the metal core 21. Leakage of electricity of the metal cores 21 can be reduced by using the first insulation layer 30 to isolate the metal cores 21 from each other, thereby improving performance of the semiconductor device.

An embodiment of the present application also provides a manufacturing method for a semiconductor device, as shown in FIG. 9. FIG. 9 is a flowchart of a manufacturing method for a semiconductor device provided by an embodiment of the present application. The manufacturing method can specifically include the following steps.

Step S100: forming a stacked structure, where the stacked structure includes alternating disposed metal layers and spacer layers.

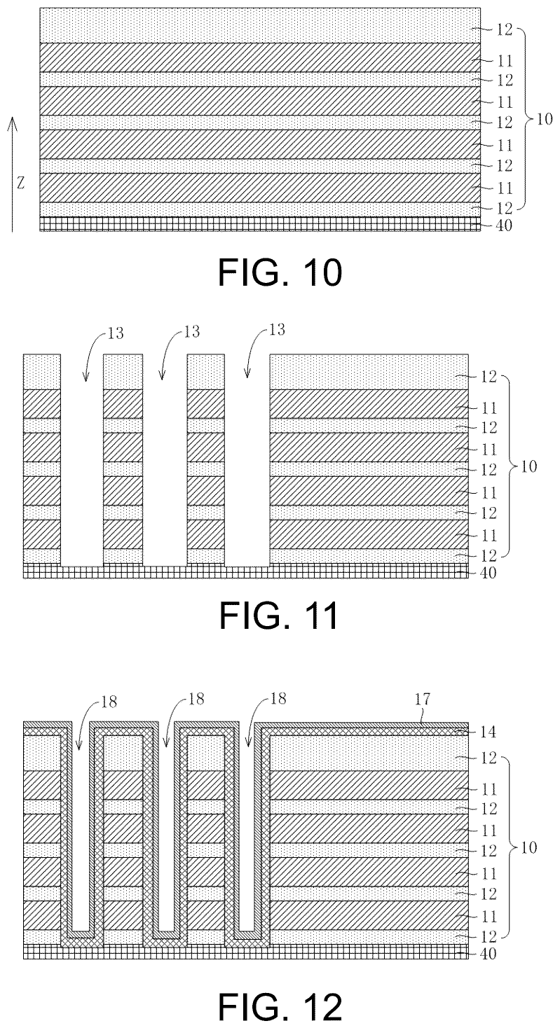

Referring to FIG. 10, FIG. 10 is a schematic diagram of a stacked structure after being formed of an embodiment of the present application. The stacked structure 10 can be formed on a second insulation layer 40 or a third insulation layer 50. The materials of the second insulation layer 40 and the third insulation layer 50 are different from the material of the stacked structure 10. The second insulation layer 40 or the third insulation layer 50 provides support for the stacked structure 10 and separates a film layer below the second insulation layer 40 or the third insulation layer 50 from the stacked structure 10. A stacking direction of the stacked structure 10 can be vertical (a direction Z shown in FIG. 10), along the direction, the metal layers 11 and the spacer layers 12 are disposed alternately and contacted with each other. Both the metal layer 11 and the spacer layer 12 can be disposed with at least two layers.

Exemplarily, as shown in FIG. 10, the metal layer 11 is disposed with four layers, and the spacer layer 12 is disposed with five layers. Along a vertical direction, the four metal layers 11 and the five spacer layers 12 are disposed alternately. One metal layer 11 is disposed between the two adjacent spacer layers 12, and one spacer layer 12 is disposed between the two adjacent metal layers 11. The metal layer 11 is made of metal material, for example, the material of metal layer 11 includes tungsten or tungsten alloy. The spacer layer 12 is made of insulation material to isolate the adjacent metal layers 11. For example, the material of the spacer layer 12 includes silicon oxide, silicon oxynitride, silicon nitride, carbon nitride, etc.

In some possible implementations, both the metal layer 11 and the spacer layer 12 can be formed by a deposition process, the deposition process includes chemical vapor deposition (CVD), or physical vapor deposition (PVD), atomic layer deposition (ALD), etc. Exemplarily, the material of the spacer layer 12 includes silicon oxide, and its precursor includes tetraethoxysilane (TEOS).

Step S200: forming a connection structure, where the connection structure runs through the stacked structure, and the connection structure includes a metal core located inside the stacked structure, a metal oxide layer located on a sidewall of the metal core, and a barrier layer located between the metal oxide layer and the metal core; where a top surface of the metal oxide layer and a top surface of the barrier layer are not equal in height and the metal oxide layer is in direct contact with the stacked structure.

A top surface of the metal core 21 is exposed to a top surface of the stacked structure 10 for an external connection. A bottom surface of the metal core 21 is exposed to a bottom surface of the stacked structure 10 for an electrical connection with a substrate. The metal core 21 can extend along the stacking direction of the stacked structure 10 to facilitate preparation of the metal core 21. The metal core 21 is made of metal material 16, such as tungsten and tungsten alloy.

The metal oxide layer 23 is located on a sidewall of the metal core 21, and the barrier layer 22 is located between the metal oxide layer 23 and the metal core 21. The barrier layer 22 separates the metal oxide layer 23 from the metal core 21, which prevents diffusion of metal ions inside the metal core 21 into the metal oxide layer 23, thereby ensuring insulation performance of the metal oxide layer 23. The metal oxide layer 23 electrically isolates the metal core 21 and/or the barrier layer 22 from the stacked structure 10, thereby ensuring electrical performance of the semiconductor device.

Where, the barrier layer 22 is in direct contact with the sidewall of the metal core 21, the metal oxide layer 23 is in direct contact with a sidewall of the barrier layer 22 away from the metal core 21 (i.e., an outer sidewall of the barrier layer 22), and the materials of the barrier layer 22 can include titanium nitride, tantalum nitride, etc. The metal oxide layer 23 is in direct contact with the stacked structure 10, for example, a sidewall of the metal oxide layer 23 away from the metal core 21 (i.e. an outer sidewall of the metal oxide layer 23) is in direct contact with the stacked structure 10 to insulate the stacked structure 10 by using the metal oxide layer 23. The materials of metal oxide layer 23 can include hafnium silicon oxide, hafnium oxide, zirconia, tantalum oxide, titanium oxide, etc. In this way, the metal oxide layer 23 has a high dielectric constant, which can improve insulation performance thereof.

A top surface of the metal oxide layer 23 and a top surface of the barrier layer 22 are not equal in height, that is, the top surface of the metal oxide layer 23 and the top surface of the barrier layer 22 are not flush. As an embodiment, the top surface of the metal oxide layer 23 is higher than the top surface of the barrier layer 22, which can improve an isolation effect of the metal oxide layer 23, effectively avoid a contact between the barrier layer 22 and the stacked structure 10, and especially avoid a contact between the barrier layer 22 and the metal layer 11. As another embodiment, the top surface of the blocking layer 22 is higher than the top surface of the metal oxide layer 23, which can improve a barrier effect of the blocking layer 22 and effectively avoid a contact between the metal oxide layer 23 and the metal core 21.

Step S300: forming a first insulation layer, where the first insulation layer is in direct contact with the sidewall of the metal core.

The first insulation layer 30 can be formed by the deposition process, the first insulation layer 30 is in direct contact with the sidewall of the metal core 21. Specifically, the first insulation layer 30 is in direct contact with a sidewall of a part of the metal core 21 that extends outward from the stacked structure 10 to isolate that the part of the metal core 21. Where a top surface of the first insulation layer 30 can be flush with the top surface of the metal core 21, so that the top surface of the metal core 21 is exposed for the external connection.

The first insulation layer 30 is in direct contact with the top surface of the barrier layer 22, that is, the top surface of the first insulation layer 30 is higher than the top surface of the barrier layer 22, so that the first insulation layer 30 covers the barrier layer 22, thereby avoiding an exposure of the barrier layer 22 and reducing oxidation of barrier layer 22. Where the first insulation layer 30 can at least cover the top surface of the stacked structure 10 and the top surface of the metal oxide layer 23, that is, the top surface of the first insulation layer 30 is higher than the top surface of the stacked structure 10 and the top surface of the metal oxide layer 23. In this way, the barrier layer 22, the stacked structure 10, and the metal oxide layer 23 are all located below the first insulation layer 30, which enable the first insulation layer 30 to isolate and protect them.

As a possible embodiment, the top surface of the barrier layer 22 is higher than the top surface of the metal oxide layer 23, and the first insulation layer 30 also covers an outer sidewall of the barrier layer 22. As another possible embodiment, the top surface of the metal oxide layer 23 is higher than the top surface of the stacked structure 10, and the first insulation layer 30 also covers an outer sidewall of the metal oxide layer 23. As yet another possible embodiment, the top surface of the metal oxide layer 23 is higher than the top surface of the barrier layer 22, and the first insulation layer 30 also covers an inner sidewall of the metal oxide layer 23. Where the outer sidewall refers to a sidewall away from the metal core 21, and the inner sidewall refers to a sidewall near the metal core 21.

Referring to FIG. 11 to FIG. 18, which are schematic diagrams of a formation of a connection structure provided by an embodiment of the present application, the forming the connection structure 20 (step S200) may include the following.

Step S201: etching the stacked structure 10 to form a hole structure 13 that runs through the stacked structure 10.

As shown in FIG. 10 and FIG. 11, each metal layer 11 and each spacer layer 12 are etched by a dry etching or a wet etching to form the hole structure 13, which runs through each metal layer 11 and each spacer layer 12. As a possible embodiment, the hole structure 13 also extends to a second insulation layer 40 or a third insulation layer 50 below the stacked structure 10. The hole structure 13 includes multiple first holes disposed at intervals, and a cross-sectional shape and an arrangement of the first holes are not limited.

Step S202: forming a metal oxide layer 23 on a sidewall of the hole structure 13 and depositing barrier material 15 and metal material 16 in sequence, where a top surface of the metal material 16 is higher than a top surface of the stacked structure 10.

As a possible implementation, the metal oxide layer 23 can be formed through the following processes.

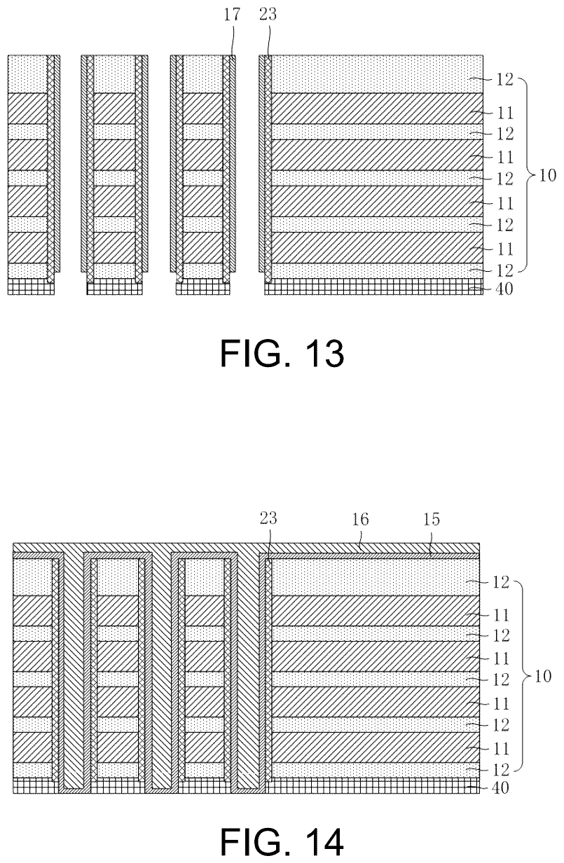

Referring to FIG. 11 and FIG. 12, metal oxide material 14 is deposed to cover a sidewall and a bottom wall of the hole structure 13, as well as the top surface of the stacked structure 10. The hole structure 13 is not fully filled with the metal oxide material 14, and the metal oxide material 14 located inside the hole structure 13 is enclosed to form a second hole.

Sacrificial material 17 is deposed to cover the metal oxide material 14, i.e., the sacrificial material 17 covers a sidewall and a bottom wall of the second hole, as well as the metal oxide material 14 located above the stacked structure 10. The second hole is not filled with the sacrificial material 17, and the sacrificial material 17 located inside the second hole is enclosed to form a third hole 18.

Referring to FIG. 12 and FIG. 13, the sacrificial material 17 and the metal oxide material 14 are re-etched, the metal oxide material 14 and the sacrificial material 17 located above the stacked structure 10 as well as the metal oxide material 14 and the sacrificial material 17 located at a bottom of the third hole 18 are removed. The metal oxide material 14 and the sacrificial material 17 located on the sidewall of the hole structure 13 are retained, and the remaining metal oxide material 14 forms the metal oxide layer 23. The third hole 18 can also run through a second insulation layer 40 or a third insulation layer 50 below the stacked structure 10 to facilitate an electrical connection with the substrate.

The remaining sacrificial material 17 is removed to expose the metal oxide layer 23. Where the sacrificial material 17 can be polycrystalline silicon, so that the sacrificial material 17 and the metal oxide layer 23 have a certain etching selectivity ratio, which reduce an impact of removing the sacrificial material 17 on the metal oxide layer 23, so as to maintain the metal oxide layer 23 covering the sidewall of the hole structure 13.

Referring to FIG. 14, after a formation of the metal oxide layer 23, barrier material 15 is deposed to cover the top surface of the stacked structure 10, the top surface and the sidewall of the metal oxide layer 23, and the bottom wall of the hole structure 13. The hole structure 13 is not fully filled with the barrier material 15. The metal material 16 is deposed to cover the barrier material 15 and fully fill the remaining hole structure 13. A top surface of the metal material 16 is higher than a top surface of the barrier material 15. In this way, the top surface of metal material 16 is relatively flat, which is easy to dispose other film layers.

Step S203: patterning the barrier material 15 and the metal material 16 to form the barrier layer 22 and the metal core 21, respectively, where the top surface of the barrier layer 22 is higher than the top surface of the metal oxide layer 23.

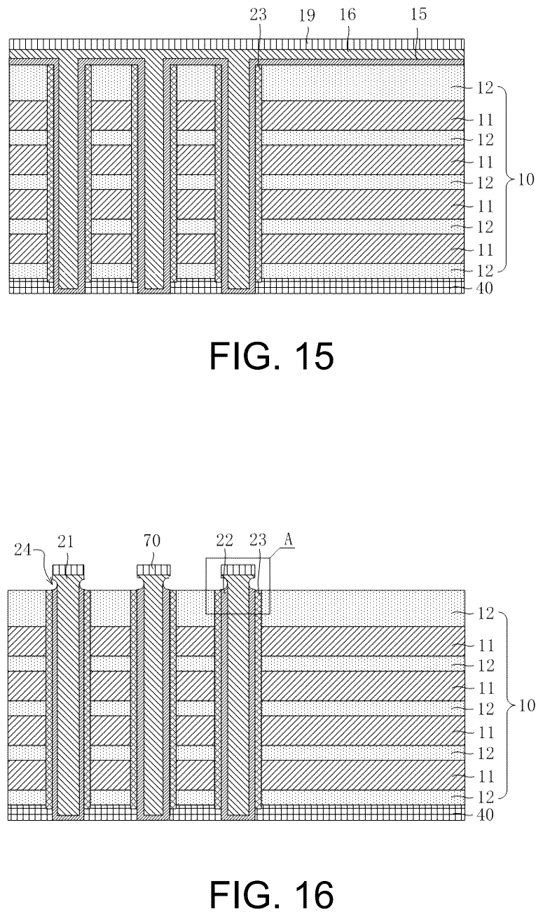

Referring to FIG. 15, protective material 19 is deposited to cover the metal material 16 to reduce oxidation of metal material 16. The protective material 19 can be silicon oxide, silicon nitride, silicon oxynitride, etc. Referring to FIG. 16, parts of the protective material 19, the barrier material 15, and the metal material 16 are removed by gluing, exposing, developing, etching, etc. The remaining protective material 19 forms a protective layer 70, the remaining blocking material 15 forms the barrier layer 22, and the remaining metal material 16 forms the metal core 21. The protective layer 70 is located on the top surface of the metal core 21, the barrier layer 22 is located on the sidewall of the metal core 21, and sidewalls of the protective layer 70, the barrier layer 22, and the metal core 21 are basically aligned.

In some possible embodiments, the barrier layer 22 is in direct contact with the top surface of the metal oxide layer 23, that is, a part of the barrier layer 22 is extended on the metal oxide layer 23, and correspondingly, a part of the metal core 21 and a part of the protective layer 70 are located on the metal oxide layer 23. In other possible embodiments, the barrier layer 22 and the metal oxide layer 23 are not equal in height, that is, the barrier layer 22 is not contacted with the top surface of the metal oxide layer 23.

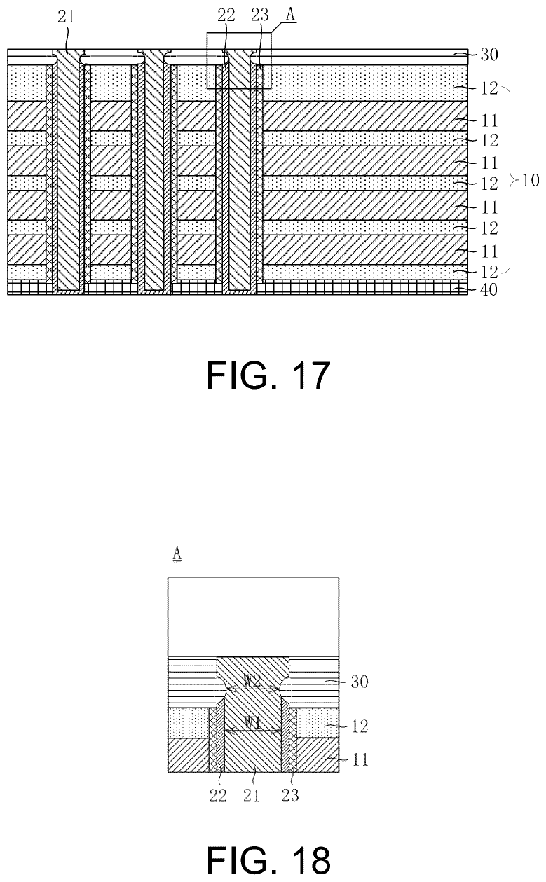

Referring to FIG. 16, as a possible embodiment, the forming the connection structure 20 (step S200) may further include: at least etching the metal core 21 to form an inward extended concavity 24 thereon, so as to increase a spacing between the part metal cores 21 that extend outward from the stacked structure 10. In this way, referring to FIG. 17 and FIG. 18, after the formation of the first insulation layer 30, the first insulation layer 30 is also filled in the concavity 24, thereby reducing leakage of electricity of the metal core 21 and improving performance of the semiconductor device.

Where, a depth of the concavity 24 is gradually increased along a direction closing to a top surface of the metal core 21. In this way, a part of the metal core 21 that extends outward from the stacked structure 10 gradually shrinks upwards, thereby causing a width of the metal core 21 gradually decreases upwards, thereby ensuring the spacing between the metal cores 21. Where a cross-sectional shape of the concavity 24 is not limited, for example, the cross-sectional shape of the concavity 24 can be trapezoidal, or arched or curved.

It can be understood that the barrier layer 22 and the metal oxide layer 23 can be formed to different states by controlling process parameters of etching the metal core 21, such as a composition of etching gas, etching temperature, etc. In some possible embodiments, the metal core 21 and the barrier layer 22 are etched, the inward extended concavity 24 is formed on the metal core 21, and the top position of the barrier layer 22 is lowered. Where, the top surface of the barrier layer 22 after etching can still be higher than the top surface of the metal oxide layer 23, and/or higher than the top surface of the stacked structure 10. In other possible embodiments, the metal core 21, the barrier layer 22, and the metal oxide layer 23 are etched, the inward extended concavity 24 is formed on the metal core 21, and the top positions of the barrier layer 22 and the metal oxide layer 23 are lowered. When an etching rate of the barrier layer 22 is higher than that of the metal oxide layer 23, the top surface of the barrier layer 22 is lower than that of the metal oxide layer 23; and when an etching rate of the metal oxide layer 23 is higher than that of the barrier layer 22, the top surface of the barrier layer 22 is higher than that of the metal oxide layer 23.

In summary, in the manufacturing method for a semiconductor device provided by the embodiment of the present application, the stacked structure 10 including alternating disposed metal layers 11 and spacer layers 12, and the connection structure 20 that runs through the stacked structure 10, as well as the first insulation layer 30 that is in direct contact with the sidewall of the metal core 21 are formed. The connection structure 20 includes the metal core 21 located inside the stacked structure 10, the metal oxide layer 23, and the barrier layer 22. Where the metal oxide layer 23 is located on the sidewall of the metal core 21, and the barrier layer 22 is located between the metal oxide layer 23 and the metal core 21 to reduce or even to avoid diffusion of metal ions inside the metal core 21 to the metal oxide layer 23, thereby ensuring performance of the metal oxide layer 23. The top surface of the metal oxide layer 23 and the top surface of the barrier layer 22 are not equal in height, and the metal oxide layer 23 is also in direct contact with the stacked structure 10, thereby avoiding contact and conduction between the stacked structure 10 and the metal core 21 and/or the barrier layer 22, and ensuring performance of the semiconductor device. Leakage of electricity of the metal core 21 can be reduced by utilizing the first insulation layer 30 to isolate the metal cores 21 from each other, thereby improving the performance of the semiconductor device.

Each embodiment or implementation is described in a progressive manner in the specification, and each embodiment focuses on differences from other embodiments, the same and similar parts between each embodiment can be referred to each other. The description of reference terms such as “an implementation”, “some implementations”, “illustrative implementations”, “embodiments”, “specific embodiments”, or “some embodiments” refers to the specific features, structures, materials, or characteristics described in combination with the implementations or embodiments being included in at least one implementation or embodiment of the present application. In the specification, schematic representations of the above terms do not necessarily refer to the same implementations or embodiments. Moreover, the specific features, the structures, the materials, or the characteristics described may be combined in any one or more of the implementations or embodiments in a suitable manner.

Finally, it should be noted that the above embodiments are only used to illustrate the technical solution of the present application and not to limit it. Although a detailed explanation of the present application has been provided with reference to the above embodiments, persons of ordinary skill in the art should understand that they can still modify the technical solutions recorded in the above embodiments, or equivalently replace some or all of technical features therein. These modifications or replacements do not make the essence of the corresponding technical solutions depart from the scope of the technical solutions in the various embodiments of the present application.

What is claimed is:

1. A semiconductor device, comprising:
a stacked structure, comprising alternating disposed metal layers and spacer layers;
a connection structure, running through the stacked structure, and comprising a metal core located inside the stacked structure, a metal oxide layer located on a sidewall of the metal core, and a barrier layer located between the metal oxide layer and the metal core;
a first insulation layer, being in direct contact with the sidewall of the metal core;
wherein a top surface of the metal oxide layer and a top surface of the barrier layer are not equal in height and the metal oxide layer is in direct contact with the stacked structure.

2. The semiconductor device according to claim 1, wherein the first insulation layer is in direct contact with the top surface of the barrier layer.

3. The semiconductor device according to claim 1, wherein the barrier layer is in direct contact with the top surface of the metal oxide layer.

4. The semiconductor device according to claim 1, wherein the metal core is provided with an inward extended concavity, and the concavity is filled with the first insulation layer.

5. The semiconductor device according to claim 4, wherein a depth of the concavity is gradually increased along a direction closing to a top surface of the metal core.

6. The semiconductor device according to claim 1, wherein the top surface of the metal oxide layer is lower than a top surface of the stacked structure.

7. The semiconductor device according to claim 1, wherein the top surface of the barrier layer is lower than the top surface of the metal oxide layer.

8. The semiconductor device according to claim 1, wherein the top surface of the barrier layer is higher than a top surface of the stacked structure.

9. The semiconductor device according to claim 1, wherein the top surface of the barrier layer is higher than the top surface of the metal oxide layer.

10. A manufacturing method for a semiconductor device, comprising:
forming a stacked structure, wherein the stacked structure comprises alternating disposed metal layers and spacer layers;
forming a connection structure, wherein the connection structure runs through the stacked structure, and the connection structure comprises a metal core located inside the stacked structure, a metal oxide layer located on a sidewall of the metal core, and a barrier layer located between the metal oxide layer and the metal core; wherein a top surface of the metal oxide layer and a top surface of the barrier layer are not equal in height and the metal oxide layer is in direct contact with the stacked structure; and
forming a first insulation layer, wherein the first insulation layer is in direct contact with the sidewall of the metal core.

11. The manufacturing method according to claim 10, wherein the forming the connection structure comprises:
etching the stacked structure to form a hole structure that runs through the stacked structure;
forming the metal oxide layer on a sidewall of the hole structure and depositing barrier material and metal material in sequence, wherein a top surface of the metal material is higher than a top surface of the stacked structure;
patterning the barrier material and the metal material to form the barrier layer and the metal core, respectively, wherein the top surface of the barrier layer is higher than the top surface of the metal oxide layer.

12. The manufacturing method according to claim 11, wherein the first insulation layer is in direct contact with the top surface of the barrier layer.

13. The manufacturing method according to claim 10, wherein the forming the connection structure further comprises:
at least etching the metal core to form an inward extended concavity of the metal core.

14. The manufacturing method according to claim 13, wherein a depth of the concavity is gradually increased along a direction closing to a top surface of the metal core.

15. The manufacturing method according to claim 10, wherein the barrier layer is in direct contact with the top surface of the metal oxide layer.

16. The manufacturing method according to claim 10, wherein the top surface of the metal oxide layer is lower than a top surface of the stacked structure.

17. The manufacturing method according to claim 10, wherein the top surface of the barrier layer is lower than the top surface of the metal oxide layer.

18. The manufacturing method according to claim 10, wherein the top surface of the barrier layer is higher than a top surface of the stacked structure.

19. The manufacturing method according to claim 13, wherein the concavity is filled with the first insulation layer.
